(19) United States
(12) Patent Application Publication
(10) Pub. No.: US 2026/0047280 A1
(43) Pub. Date: Feb. 12, 2026

(54) DISPLAY PANEL, MANUFACTURING METHOD THEREOF, AND DISPLAY DEVICE

(71) Applicant: HKC CORPORATION LIMITED, Shenzhen (CN)

(72) Inventors: Zhihao Wang, Shenzhen (CN); Wenqin ZHAO, Shenzhen (CN); Kang LV, Shenzhen (CN); Yun LIN, Shenzhen (CN); Jun SHI, Shenzhen (CN); Rui JIANG, Shenzhen (CN); Lidan YE, Shenzhen (CN)

(21) Appl. No.: 19/291,020

(22) Filed: Aug. 5, 2025

(30) Foreign Application Priority Data
Aug. 9, 2024 (CN) 202411091676.6

(51) Int. Cl. H10K 59/122; H10K 59/12; H10K 59/124; H10K 59/131; H10K 59/35

(52) U.S. Cl. CPC H10K 59/122; H10K 59/1201; H10K 59/124; H10K 59/131; H10K 59/35

(57) ABSTRACT

A display panel includes a substrate, a driving circuit layer, a pixel definition layer, and a plurality of stacked sub-pixels. The driving circuit layer is provided on a side of the substrate, and the pixel definition layer is provided on the side of the driving circuit layer away from the substrate. The plurality of stacked sub-pixels are stacked on the side of the driving circuit layer away from the substrate in the vertical direction and are located within the pixel definition layer. The orthographic projections of at least some of the stacked sub-pixels on the driving circuit layer overlap. The stacked sub-pixels include an anode, a light-emitting part, and a cathode that are sequentially arranged and connected in the horizontal direction.

### CROSS-REFERENCE TO RELATED APPLICATIONS

The present application claims priority to Chinese Patent Application No. 202411091676.6, filed Aug. 9, 2024, the entire disclosure of which is hereby incorporated herein by reference.

### TECHNICAL FIELD

The present application relates to the technical field of display, and particularly to a display panel, a manufacturing method thereof, and a display device.

### BACKGROUND

Organic Light-Emitting Diode (OLED) display panels do not require a backlight source, and have advantages such as bendability, thin thickness, high brightness, low power consumption, fast response, and a wide color gamut. Therefore, they are widely used in devices such as mobile phones and laptops.

The display panel includes pixel units arranged in an array, and each pixel unit contains at least two sub-pixels of different colors. For example, a pixel unit includes a red sub-pixel, a green sub-pixel, and a blue sub-pixel to achieve color (RGB) display.

The light-emitting parts of the red sub-pixel, the green sub-pixel, and the blue sub-pixel can be fabricated by evaporation using a Fine Metal Mask (FMM). Due to the limitation of the process precision of the manufacturing process for the light-emitting parts of the red, green, and blue sub-pixels, a group of red, green, and blue sub-pixels occupies a large space on the display panel, which limits the improvement of the pixel density (PPI) of the display panel.

### SUMMARY

There are provided a display panel, a manufacturing method thereof, and a display device according to embodiments of the present application. The technical solution is as below.

According to a first aspect of embodiments of the present application, there is provided a display panel, which includes a substrate and a driving circuit layer. The driving circuit layer is provided on a side of the substrate, the display panel further includes:
a pixel definition layer, provided on a side of the driving circuit layer away from the substrate;
a plurality of stacked sub-pixels, stacked on the side of the driving circuit layer away from the substrate in a vertical direction and located in the pixel definition layer;
orthographic projections of at least some of the plurality of stacked sub-pixels on the driving circuit layer overlap; and
each stacked sub-pixel includes an anode, a light-emitting part, and a cathode that are sequentially arranged and connected in a horizontal direction.

According to a second aspect of embodiments of the present application, there is provided a method for manufacturing a display panel, applied to manufacture the display panel, the method includes:
forming the driving circuit layer on the substrate;
forming the pixel definition layer on the side of the driving circuit layer away from the substrate; and
forming the plurality of stacked sub-pixels in pixel openings of the pixel definition layer, wherein the orthographic projections of at least some of the plurality of stacked sub-pixels on the driving circuit layer overlap.

According to a third aspect of embodiments of the present application, there is provided a display device, including:
the display panel;
a main board, connected to the display panel.

Other characteristics and advantages of the present application will become apparent through the following detailed description, or will be learned partially through the practice of the present application.

It should be understood that the above general description and the following detailed description are only exemplary and explanatory, and shall not limit the disclosure.

### BRIEF DESCRIPTION OF THE DRAWINGS

The accompanying drawings herein are incorporated into the specification and constitute a part of the specification, showing the embodiments conforming to the present application, and are used together with the specification to explain the principles of the present application. Obviously, the accompanying drawings in the following description are only some embodiments of the present application. For those skilled in the art, other accompanying drawings can also be obtained according to these accompanying drawings without creative efforts.

FIG. 1 is a schematic structural view of the display panel in the first embodiment of the present application.

FIG. 2 is a schematic structural view of the anode layer of the display panel in the first embodiment of the present application.

FIG. 3 is a schematic cross-sectional view in line A-A in FIG. 2.

FIG. 4 is a schematic structural view of the cathode layer of the display panel in the first embodiment of the present application.

FIG. 5 is a schematic view of the light emission of the green sub-pixel in the first embodiment of the present application.

FIG. 6 is a schematic view of the light emission of the red sub-pixel in the first embodiment of the present application.

FIG. 7 is a schematic view of the light emission of the blue sub-pixel in the first embodiment of the present application.

FIG. 8 is a flowchart of a method for manufacturing the display panel in the second embodiment of the present application.

FIG. 9 is a schematic structural diagram of the display device in the third embodiment of the present application.

### DETAILED DESCRIPTION OF THE EMBODIMENTS

Now, the example embodiments will be described more comprehensively with reference to the accompanying drawings. However, the example embodiments can be implemented in various forms and should not be construed as being limited to the examples set forth herein. Instead, these embodiments are provided so that the present application will be more comprehensive and complete, and the concept of the example embodiments will be fully conveyed to those skilled in the art.

Moreover, the described features, structures, or characteristics can be combined in any suitable manner in one or more embodiments. In the following description, many specific details are provided to give a full understanding of the embodiments of the present application. However, those skilled in the art will realize that the technical solutions of the present application can be practiced without one or more of the specific details, or other methods, components, devices, steps, etc. can be adopted. In other cases, well-known methods, devices, implementations, or operations are not shown or described in detail to avoid obscuring various aspects of the present application.

Hereinafter, the present application will be further described in detail with reference to the accompanying drawings and specific embodiments. It should be noted here that the technical features involved in the various embodiments of the present application described below can be combined with each other as long as they do not conflict with each other. The embodiments described below with reference to the accompanying drawings are exemplary and are intended to explain the present application, and should not be construed as a limitation to the present application.

### The First Embodiment

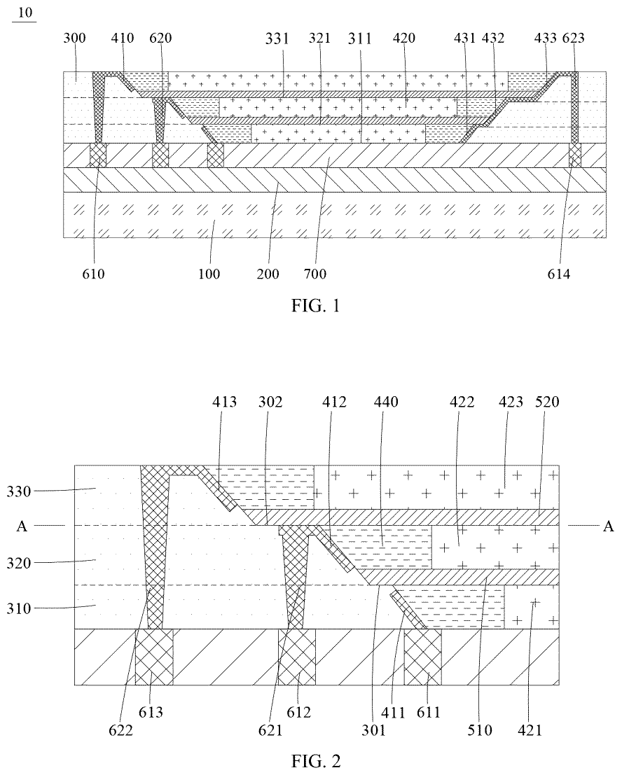

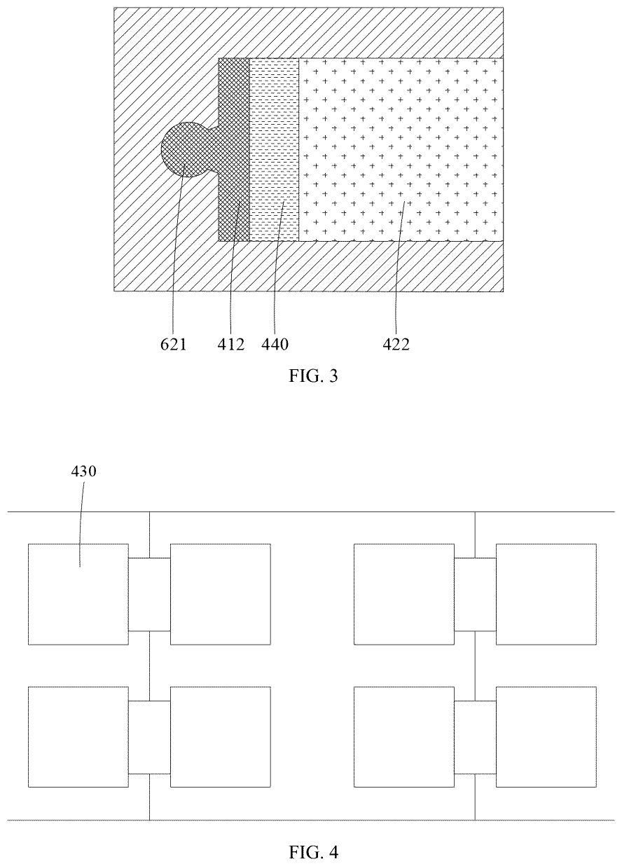

As shown in FIGS. 1 to 4, in this embodiment, the display panel 10 includes a substrate 100, a driving circuit layer 200, a pixel definition layer 300, and a pixel structure layer. The driving circuit layer 200 is provided on a side of the substrate 100. The substrate 100 includes a circuit carrier such as a glass substrate, a polyethylene terephthalate (PET) substrate, or a polyimide (PI) substrate. The substrate 100 may also include silicon nitride compounds (SiNx) and silicon oxide compounds (SiOx) provided on the circuit carrier to further enhance the functions of water and oxygen isolation and electrostatic shielding. The driving circuit layer 200 includes a pixel driving circuit.

The pixel definition layer 300 is provided on a side of the driving circuit layer 200 away from the substrate 100. The pixel structure layer includes a plurality of stacked sub-pixels. The plurality of stacked sub-pixels are stacked on the side of the driving circuit layer 200 away from the substrate 100 in a vertical direction and are located in pixel openings of the pixel definition layer 300. The orthographic projections of at least some of the stacked sub-pixels on the driving circuit layer 200 overlap. Each stacked sub-pixel include an anode, a light-emitting part, and a cathode that are sequentially arranged and connected in a horizontal direction.

It should be noted that the plurality of stacked sub-pixels stacked in the vertical direction can be sub-pixels of different colors, but it is not limited to this. The plurality of sub-pixels stacked in the vertical direction can also be sub-pixels of the same color, which can be determined according to the specific situation. In addition, the pixel structure layer may also include non-stacked sub-pixels located on a side of plurality of the stacked sub-pixels. The plurality of stacked sub-pixels form a pixel unit, or the plurality of stacked sub-pixels and non-stacked sub-pixels together form a pixel unit. The plurality of sub-pixels in the pixel unit include red sub-pixels, green sub-pixels, and blue sub-pixels to achieve Red, Green, Blue (RGB) color display.

In some technical solutions, the light-emitting parts of different-colored sub-pixels in the pixel unit are arranged on the same pixel plane. Due to limitation of the process precision of the manufacturing process for the light-emitting parts of the red, green, and blue sub-pixels, a group of red, green, and blue sub-pixels occupies a large space on the display panel 10, which limits the improvement of the pixel density of the display panel 10.

In this embodiment, the display panel 10 includes a substrate 100, a driving circuit layer 200, a pixel definition layer 300, and a plurality of stacked sub-pixels. The driving circuit layer 200 is provided on the side of the substrate 100, the pixel definition layer 300 is provided on the side of the driving circuit layer 200 away from the substrate 100. The plurality of stacked sub-pixels are stacked on the side of the driving circuit layer 200 away from the substrate 100 in the vertical direction and are located in the pixel openings of the pixel definition layer 300. The orthographic projections of at least some of the stacked sub-pixels on the driving circuit layer 200 overlap. Each stacked sub-pixel include an anode, a light-emitting part, and a cathode that are sequentially arranged and connected in the horizontal direction. That is, by stacking at least some of the plurality of stacked sub-pixels of the pixel unit in the vertical direction, the design space of the display panel 10 occupied by the plurality of stacked sub-pixels is reduced, and the pixel density of the display panel 10 is improved.

As shown in FIGS. 1 to 4, the pixel definition layer 300 includes a first organic layer 310, a second organic layer 320, and a third organic layer 330. The second organic layer 320 is located on the side of the first organic layer 310 away from the substrate 100, and the third organic layer 330 is located on the side of the second organic layer 320 away from the substrate 100. The horizontal direction includes a row direction and a column direction that are perpendicular to each other. The first organic layer 310 includes a plurality of first pixel openings 311 arranged in an array in the row direction and the column direction. The second organic layer 320 includes a plurality of second pixel openings 321 arranged in an array in the row direction and the column direction. The third organic layer 330 includes a plurality of third pixel openings 331 arranged in an array in the row direction and the column direction. The first pixel openings 311 and the second pixel openings 321 at least partially overlap, and the second pixel openings 321 and the third pixel openings 331 at least partially overlap. The pixel openings of the pixel definition layer 300 include the first pixel openings 311, the second pixel openings 321, and the third pixel openings 331.

The plurality of stacked sub-pixels include a first sub-pixel, a second sub-pixel, and a third sub-pixel. The first sub-pixel is located in the first pixel opening 311, the second sub-pixel is located in the second pixel opening 321, and the third sub-pixel is located in the third pixel opening 331.

The three stacked sub-pixels of the pixel unit are stacked in the vertical direction, which further reduces the design space of the display panel 10 occupied by the stacked sub-pixels and improves the pixel density of the display panel 10.

It should be noted that three of the plurality of sub-pixels (stacked sub-pixels) in the pixel unit can be stacked, but it is not limited to this. Two of the plurality of sub-pixels (stacked sub-pixels) in the pixel unit can also be stacked, and the other one or more sub-pixels (non-stacked sub-pixels) can be arranged on a side of any stacked sub-pixel in the row direction or the column direction to reduce the process difficulty, which can be determined according to the specific situation.

In some embodiments, the orthographic projection of the first pixel opening 311 on the second organic layer 320 is located within the second pixel opening 321, and the orthographic projection of the second pixel opening 321 on the third organic layer 330 is located within the third pixel opening 331 of the third organic layer 330. A first step surface 301 is provided between the first pixel opening 311 and the second pixel opening 321, and a second step surface 302 is provided between the second pixel opening 321 and the third pixel opening 331.

The pixel structure layer includes an anode layer 410, a light-emitting layer 420, and a cathode layer 430. The anode layer 410 includes a first anode 411, a second anode 412, and a third anode 413. The light-emitting layer 420 includes a first light-emitting part 421, a second light-emitting part 422, and a third light-emitting part 423. The cathode layer 430 includes a first cathode 431, a second cathode 432, and a third cathode 433.

The first sub-pixel includes a first anode 411, a first light-emitting part 421, and a first cathode 431. The first anode 411 and the first cathode 431 are respectively located on the first side wall and the second side edge of the first pixel opening 311 in the row direction that are opposite. The second sub-pixel includes a second anode 412, a second light-emitting part 422, and a second cathode 432. The second anode 412 and the second cathode 432 are respectively located on the first side wall and the second side edge of the second pixel opening 321 in the row direction that are opposite. The third sub-pixel includes a third anode 413, a third light-emitting part 423, and a third cathode 433. The third anode 413 and the third cathode 433 are respectively located on the first side wall and the second side edge of the third pixel opening 331 in the row direction that are opposite. The sizes of the first pixel opening 311, the second pixel opening 321, and the third pixel opening 331 gradually increase, and the design spaces of the display panel 10 occupied by the first light-emitting part 421, the second light-emitting part 422, and the third light-emitting part 423 gradually increase.

The different sizes of the first pixel opening 311, the second pixel opening 321, and the third pixel opening 331 allow the sizes of the light-emitting parts to be set according to the lifetimes and luminous efficiencies of the light-emitting parts of different stacked sub-pixels.

It should be noted that a first step surface 301 is provided between the first pixel opening 311 and the second pixel opening 321, and a second step surface 302 is provided between the second pixel opening 321 and the third pixel opening 331, but it is not limited to this. The first pixel opening 311, the second pixel opening 321, and the third pixel opening 331 can also be connected to form a conical or pyramidal pixel opening, which can be determined according to the specific situation.

For example, the manufacturing material of the first light-emitting part 421 includes a green organic light-emitting material, the manufacturing material of the second light-emitting part 422 includes a red organic light-emitting material, and the manufacturing material of the third light-emitting part 423 includes a blue organic light-emitting material. The green organic light-emitting material, the red organic light-emitting material, and the blue organic light-emitting material are all light-transmitting materials. The first sub-pixel is a green sub-pixel, the second sub-pixel is a red sub-pixel, and the third sub-pixel is a blue sub-pixel.

Since the luminous efficiency and lifetime of the blue organic light-emitting material are relatively lower, thus the third light-emitting part 423 is provided on the top layer, such that the third light-emitting part 423 is larger, which is beneficial to improving the brightness and lifetime of the blue sub-pixel.

It should be noted that since the luminous efficiencies and lifetimes of the red organic light-emitting material and the green organic light-emitting material are similar, the positions of the first light-emitting part 421 and the second light-emitting part 422 can also be interchanged, which can be determined according to the specific situation.

In some embodiments, the pixel unit further includes a white sub-pixel. Two, three, or four of the white sub-pixel, the red sub-pixel, the green sub-pixel, and the blue sub-pixel are stacked, and the position of the white sub-pixel in the vertical direction is not limited. Preferably, the white sub-pixel, the green sub-pixel, the red sub-pixel, and the blue sub-pixel are stacked in sequence.

As shown in FIGS. 1 to 4, the display panel 10 further includes a functional layer 440. The functional layer 440 is provided between the anode layer 410 and the light-emitting layer 420, and between the light-emitting layer 420 and the cathode layer 430. For each stacked sub-pixel, different functional layers 440 can be arranged between the anode and the light-emitting part and between the light-emitting part and the cathode according to the specific situation.

Specifically, the functional layer 440 may include an electron injection layer (EIL), an electron transport layer (ETL), a hole blocking layer (HBL), an electron blocking layer (EBL), a hole transport layer (HTL), and a hole injection layer (HIL). The hole injection layer, the hole transport layer, and the electron blocking layer are sequentially provided between the anode layer 410 and the light-emitting layer 420, and the hole blocking layer, the electron transport layer, and the electron injection layer are sequentially provided between the light-emitting layer 420 and the cathode layer 430.

Since the functional layers 440 such as the electron injection layer, the electron transport layer, the hole blocking layer, the electron blocking layer, the hole transport layer, and the hole injection layer are stacked in the row direction, by adjusting the thickness of the functional layer 440, the area of the light-emitting layer 420 can be appropriately increased or decreased.

It should be noted that the functional layer 440 may include an electron injection layer, an electron transport layer, a hole blocking layer, an electron blocking layer, a hole transport layer, and a hole injection layer, but it is not limited to this. In some embodiments, the functional layer 440 includes some of the electron injection layer, the electron transport layer, the hole blocking layer, the electron blocking layer, the hole transport layer, and the hole injection layer, which can be determined according to the specific situation. The functional layers 440 such as the electron injection layer, the electron transport layer, the hole blocking layer, the electron blocking layer, the hole transport layer, and the hole injection layer can be stacked in the row direction, but it is not limited to this. Some of the functional layers 440 can be stacked in the vertical direction, which can be determined according to the specific situation.

As shown in FIGS. 1 to 4, the display panel 10 further includes a first insulating layer 510 and a second insulating layer 520. The first insulating layer 510 is provided at the bottom of the second pixel opening 321 close to the substrate 100, and the parts of two sides of the first insulating layer 510 in the row direction are located on the first step surface 301. The second insulating layer 520 is provided at the bottom of the third pixel opening 331 of the third organic layer 330 close to the substrate 100, and the parts of two sides of the second insulating layer 520 in the row direction are located on the second step surface 302. Both the first insulating layer 510 and the second insulating layer 520 are light-transmitting film layers. The manufacturing materials of the first insulating layer 510 and the second insulating layer 520 include inorganic insulating materials such as silicon nitride compounds or silicon oxide compounds, and organic insulating materials such as polyimide.

By separating the light-emitting parts of different stacked sub-pixels with the first insulating layer 510 and the second insulating layer 520, crosstalk can be eliminated and the display effect can be improved.

It should be noted that the second anode 412 may extend to the first step surface 301, and the third anode 413 may extend to the second step surface 302, but it is not limited to this. The second anode 412 may also extend to the first insulating layer 510, and the third anode 413 may also extend to the second insulating layer 520, that is, the anodes are separated by the first insulating layer 510 and the second insulating layer 520.

In some embodiments, the first cathode 431 and the second cathode 432 are connected, and the second cathode 432 and the third cathode 433 are connected. The display panel 10 includes a plurality of pixel units, and the cathodes of different pixel units can be connected. The first cathode 431 or the third cathode 433 is connected to the driving circuit layer 200. The first anode 411, the second anode 412, and the third anode 413 are respectively connected to the driving circuit layer 200, and the first anode 411, the second anode 412, and the third anode 413 are not connected to each other.

The cathodes of the same pixel unit are connected and the cathodes of different pixel units are connected, which can reduce the manufacturing cost of the display panel 10.

As shown in FIGS. 1 to 4, the display panel 10 further includes a planarization layer 700, a first conductor layer 610, and a second conductor layer 620. The planarization layer 700 is provided between the driving circuit layer 200 and the pixel definition layer 300. The manufacturing material of the planarization layer 700 includes organic materials such as polyimide. The planarization layer 700 has the functions of insulating and protecting the pixel driving circuit and reducing the mutual interference between the anode and the circuit magnetic field.

The first conductor layer 610 is located in the planarization layer 700. The first conductor layer 610 includes a first vertical interconnection 611, a second vertical interconnection 612, and a third vertical interconnection 613. The first anode 411 is connected to the driving circuit layer 200 through the first vertical interconnection 611, the second anode 412 is connected to the driving circuit layer 200 through the second vertical interconnection 612, and the third anode 413 is connected to the driving circuit layer 200 through the third vertical interconnection 613. The first vertical interconnection 611, the second vertical interconnection 612, and the third vertical interconnection 613 are arranged at intervals in the row direction. The first vertical interconnection 611 can be arranged below the second pixel opening 321, and the second vertical interconnection 612 can be arranged below the third pixel opening 331.

The second conductor layer 620 is located in the pixel definition layer 300. The second conductor layer 620 includes a first conducting wire 621 and a second conducting wire 622. The first anode 411 can be directly connected to the first vertical interconnection 611, the second anode 412 is connected to the second vertical interconnection 612 through the first conducting wire 621, and the third anode 413 is connected to the third vertical interconnection 613 through the second conducting wire 622.

In addition, the first conductor layer 610 may further include a fourth vertical interconnection 614. The first cathode 431 is connected to the driving circuit layer 200 through the fourth vertical interconnection 614, or the second conductor layer 620 further includes a third conducting wire 623. The third cathode 433 is connected to the fourth vertical interconnection 614 through the third conducting wire 623, and the fourth vertical interconnection 614 passes through the planarization layer 700 to be connected to the driving circuit layer 200.

The first vertical interconnection 611, the second vertical interconnection 612, and the third vertical interconnection 613 are arranged at intervals in the row direction. The first vertical interconnection 611 can be arranged below the second pixel opening 321, and the second vertical interconnection 612 can be arranged below the third pixel opening 331, which reduces the design space of the display panel 10 occupied by the anode wiring and improves the pixel density of the display panel 10.

In some embodiments, the manufacturing material of the anode layer 410 includes metals such as titanium (Ti), aluminum (Al), silver (Ag), molybdenum (Mo) and their alloys. The anode layer 410 can be a laminated layer of indium tin oxide (ITO), a metal layer, and indium tin oxide. The material of the cathode layer 430 includes metals such as magnesium (Mg), silver (Ag) and their alloy materials. The cathode layer 430 can be a multi-layer metal laminated layer. The surfaces of the anode layer 410 and the cathode layer 430 away from the inner wall of the pixel opening can form a reflecting surface to reflect the light of the light-emitting part, so as to improve the light utilization rate. In addition, a reflecting layer can also be made on the bottom surface of the first pixel opening 311 close to the substrate 100 to reflect the light of the light-emitting part.

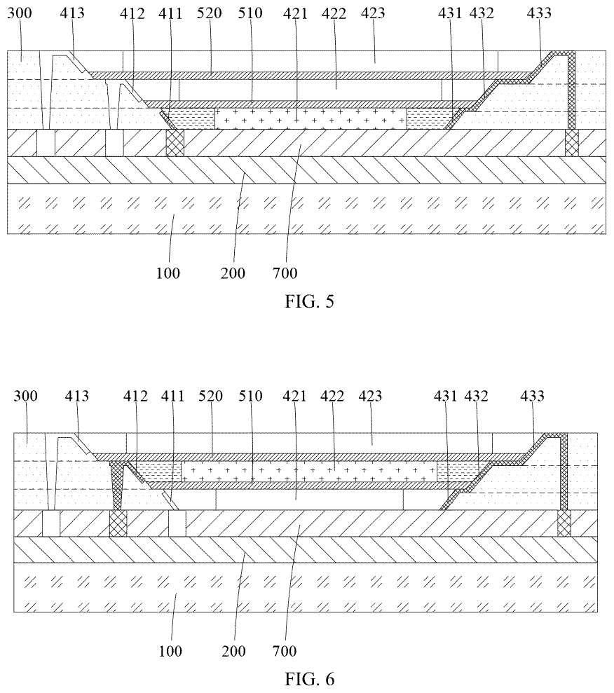

As shown in FIG. 5, when the green sub-pixel needs to emit light, the pixel driving circuit of the green sub-pixel provides current. The current flows through the first anode 411, the first light-emitting part 421, and the first cathode 431, and the first light-emitting part 421 emits light. The first insulating layer 510 isolates the first light-emitting part 421 from the second light-emitting part 422, and the second light-emitting part 422 and the third light-emitting part 423 do not emit light. It should be noted that the selection of the current flowing through the first light-emitting part 421 and the thickness and refractive index of the film layers above the first light-emitting part 421 needs to refer to the transmission and gain of green light by the encapsulation layer on the side of the pixel definition layer 300 away from the substrate 100.

As shown in FIG. 6, when the red sub-pixel needs to emit light, the pixel driving circuit of the red sub-pixel provides current. The current flows through the second anode 412, the second light-emitting part 422, and the second cathode 432, and the second light-emitting part 422 emits light. The first insulating layer 510 isolates the second light-emitting part 422 from the first light-emitting part 421, and the second insulating layer 520 isolates the second light-emitting part 422 from the third light-emitting part 423. The first light-emitting part 421 and the third light-emitting part 423 do not emit light. It should be noted that the selection of the current flowing through the second light-emitting part 422 and the thickness and refractive index of the film layers above the second light-emitting part 422 needs to refer to the transmission and gain of red light by the encapsulation layer on the side of the pixel definition layer 300 away from the substrate 100.

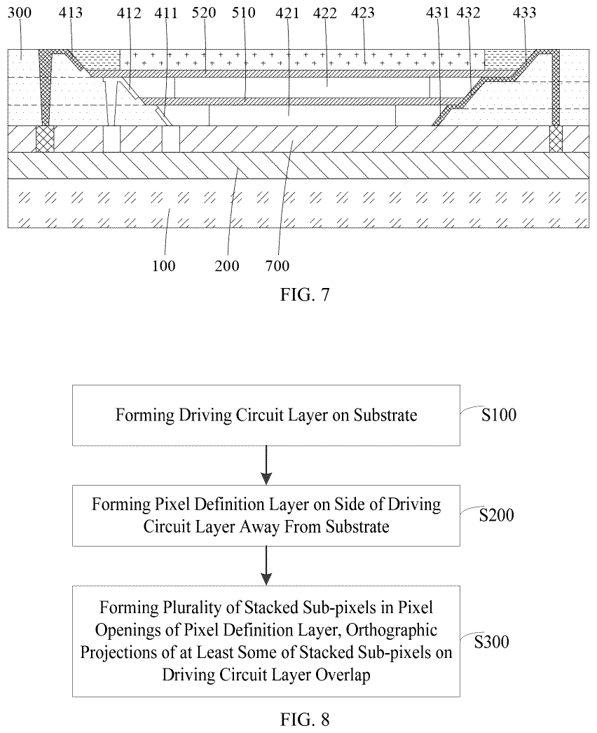

As shown in FIG. 7, when the blue sub-pixel needs to emit light, the pixel driving circuit of the blue sub-pixel provides current. The current flows through the third anode 413, the third light-emitting part 423, and the third cathode 433, and the third light-emitting part 423 emits light. The second insulating layer 520 isolates the second light-emitting part 422 from the third light-emitting part 423, and the first light-emitting part 421 and the second light-emitting part 422 do not emit light. It should be noted that the current flowing through the third light-emitting part 423 needs to refer to the transmission and gain of blue light by the encapsulation layer on the side of the pixel definition layer 300 away from the substrate 100.

### The Second Embodiment

The present application also provides a method for manufacturing the display panel 10, which is used to manufacture the display panel 10 disclosed in the first embodiment. As shown in FIG. 8, the method for manufacturing the display panel 10 includes:

S100: forming a driving circuit layer 200 on a substrate 100;

S200: forming a pixel definition layer 300 on a side of the driving circuit layer 200 away from the substrate 100;

S300: forming a plurality of stacked sub-pixels in pixel openings of the pixel definition layer 300, where orthographic projections of at least some of the stacked sub-pixels on the driving circuit layer 200 overlap.

After the driving circuit layer 200 is formed, the planarization layer 700 and the first conductor layer 610 can be sequentially formed. The first conductor layer 610 passes through the planarization layer 700 to be connected to the driving circuit layer 200, and the upper surface of the first conductor layer 610 is exposed outside the planarization layer 700. The anode layer 410 and the cathode layer 430 can be formed by a deposition process, such as chemical vapor deposition (CVD) and physical vapor deposition (PVD). The second conductor layer 620 can be formed in the same process as the anode layer 410 or the cathode layer 430.

Both the light-emitting layer 420 and the functional layer 440 can be formed by an evaporation process. The light-emitting layer 420 can be evaporated first, and then the functional layer 440 can be provided on both sides of the light-emitting layer 420 in the row direction. After evaporating the first light-emitting part 421 and the functional layers 440 on both sides of the first light-emitting part 421, the first insulating layer 510 is formed. Then, the second light-emitting part 422 and the functional layers 440 on both sides of the second light-emitting part 422 are evaporated, and then the second insulating layer 520 is formed. Finally, the third light-emitting part 423 and the functional layers 440 on both sides of the third light-emitting part 423 are evaporated. After forming the third light-emitting part 423 and the functional layers 440 on both sides of the third light-emitting part 423, an encapsulation layer is formed on the side of the pixel definition layer 300 away from the substrate 100.

It should be noted that the light-emitting layer 420 can be formed as a whole after forming the pixel definition layer 300, but it is not limited to this. The first anode 411, the first cathode 431, and the first light-emitting part 421 can be formed after forming the first organic layer 310, then the second organic layer 320 can be formed, and then the second sub-pixel and the third sub-pixel can be formed, etc., which can be determined according to the specific situation.

The pixel structure layer is formed as a whole after forming the pixel definition layer 300. The first light-emitting part 421, the second light-emitting part 422, the third light-emitting part 423, and the functional layer 440 can be continuously evaporated, thereby reducing the manufacturing cost of the display panel 10.

### The Third Embodiment

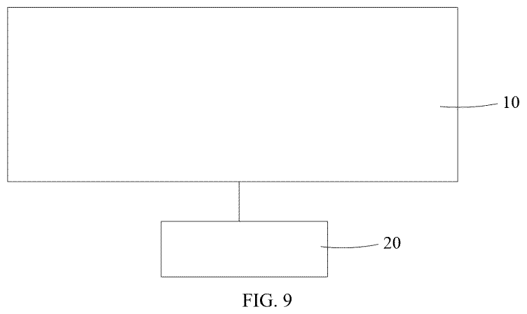

The present application also provides a display device. As shown in FIG. 9, the display device includes a display panel 10 and a main board 20, and the main board 20 is connected to the display panel 10.

The display device includes the display panel 10. The display panel 10 includes a substrate 100, a driving circuit layer 200, a pixel definition layer 300, and a plurality of stacked sub-pixels. The driving circuit layer 200 is provided on a side of the substrate 100, the pixel definition layer 300 is provided on the side of the driving circuit layer 200 away from the substrate 100. The plurality of stacked sub-pixels are stacked on the side of the driving circuit layer 200 away from the substrate 100 in the vertical direction and are located in the pixel openings of the pixel definition layer 300. The orthographic projections of at least some of the stacked sub-pixels on the driving circuit layer 200 overlap. The stacked sub-pixels include an anode, a light-emitting part, and a cathode that are sequentially arranged and connected in the horizontal direction. That is, by stacking at least some of the stacked sub-pixels in the pixel unit in the vertical direction, the design space of the display panel 10 occupied by the stacked sub-pixels is reduced, and the pixel density of the display panel 10 is improved.

The terms “first”, “second”, etc. are only used for the purpose of description and cannot be understood as indicating or implying relative importance or implicitly specifying the number of indicated technical features. Thus, a feature defined with “first”, “second”, etc. may explicitly or implicitly include one or more of this feature. In the description of the present application, the meaning of “a plurality of” is two or more, unless otherwise specifically defined.

In the present application, unless otherwise clearly defined and limited, the terms “assembly”, “connection”, etc. should be understood in a broad sense. For example, it can be a fixed connection, a detachable connection, or an integrated body; it can be a mechanical connection or an electrical connection; it can be a direct connection or an indirect connection through an intermediate medium, and it can be the internal communication of two components or the interaction relationship between two components. For those skilled in the art, the specific meaning of the above terms in the present application can be understood according to the specific situation.

In the description of this specification, the description referring to the terms “some embodiments”, “for example”, etc. means that the specific features, structures, materials, or characteristics described in combination with the embodiment or example are included in at least one embodiment or example of the present application. In this specification, the schematic expressions of the above terms do not necessarily refer to the same embodiment or example. Moreover, the described specific features, structures, materials, or characteristics can be combined in a suitable way in any one or more embodiments or examples. In addition, without contradiction, those skilled in the art can combine and integrate the different embodiments or examples described in this specification and the features of different embodiments or examples.

Although the embodiments of the present application have been shown and described above, it can be understood that the above embodiments are exemplary and should not be construed as a limitation to the present application. Those skilled in the art can make changes, modifications, substitutions, and variations to the above embodiments within the scope of the present application. Therefore, any changes or modifications made according to the claims and the specification of the present application shall fall within the scope covered by the patent of the present application.

What is claimed is:

1. A display panel, comprising a substrate and a driving circuit layer,
wherein the driving circuit layer is provided on a side of the substrate;
wherein the display panel further comprises:
a pixel definition layer, provided on a side of the driving circuit layer away from the substrate; and
a plurality of stacked sub-pixels, stacked on the side of the driving circuit layer away from the substrate in a vertical direction and located in the pixel definition layer;
wherein orthographic projections of at least some of the plurality of stacked sub-pixels on the driving circuit layer overlap; and
each stacked sub-pixel comprises an anode, a light-emitting part, and a cathode that are sequentially arranged and connected in a horizontal direction.

2. The display panel according to claim 1, wherein the pixel definition layer comprises a first organic layer, a second organic layer, and a third organic layer;
wherein the second organic layer is located on a side of the first organic layer away from the substrate, and the third organic layer is located on a side of the second organic layer away from the substrate;
the first organic layer comprises a first pixel opening, the second organic layer comprises a second pixel opening, and the third organic layer comprises a third pixel opening;
the plurality of stacked sub-pixels comprise a first sub-pixel, a second sub-pixel, and a third sub-pixel; and
the first sub-pixel is located in the first pixel opening, the second sub-pixel is located in the second pixel opening, and the third sub-pixel is located in the third pixel opening.

3. The display panel according to claim 2, wherein an orthographic projection of the first pixel opening on the second organic layer is located within the second pixel opening, and an orthographic projection of the second pixel opening on the third organic layer is located within the third pixel opening of the third organic layer;
wherein the horizontal direction comprises a row direction and a column direction that are perpendicular to each other;
the first sub-pixel comprises a first anode, a first light-emitting part, and a first cathode;
the first anode and the first cathode are respectively located on a first side wall and a second side edge of the first pixel opening in the row direction;
the second sub-pixel comprises a second anode, a second light-emitting part, and a second cathode;
the second anode and the second cathode are respectively located on a first side wall and a second side edge of the second pixel opening in the row direction;
the third sub-pixel comprises a third anode, a third light-emitting part, and a third cathode; and
the third anode, and the third cathode are respectively located on a first side wall and a second side edge of the third pixel opening in the row direction.

4. The display panel according to claim 3, wherein a manufacturing material of the first light-emitting part comprises a green organic light-emitting material, a manufacturing material of the second light-emitting part comprises a red organic light-emitting material, and a manufacturing material of the third light-emitting part comprises a blue organic light-emitting material; and
the green organic light-emitting material, the red organic light-emitting material, and the blue organic light-emitting material are all light-transmitting materials.

5. The display panel according to claim 3, further comprising a first insulating layer and a second insulating layer;
wherein the first insulating layer is provided at a bottom of the second pixel opening close to the substrate, and the second insulating layer is provided at a bottom of the third pixel opening of the third organic layer close to the substrate; and
the first insulating layer and the second insulating layer are light-transmitting film layers.

6. The display panel according to claim 3, wherein the first anode, the second anode, and the third anode are respectively connected to the driving circuit layer; and
the first cathode, the second cathode, and the third cathode are connected to each other, and the first cathode or the third cathode is connected to the driving circuit layer.

7. The display panel according to claim 6, further comprising a planarization layer and a first conductor layer;
wherein the planarization layer is provided between the driving circuit layer and the pixel definition layer;
the first conductor layer comprises a first vertical interconnection, a second vertical interconnection, and a third vertical interconnection;
the first anode is connected to the driving circuit layer through the first vertical interconnection, the second anode is connected to the driving circuit layer through the second vertical interconnection, and the third anode is connected to the driving circuit layer through the third vertical interconnection; and
the first vertical interconnection, the second vertical interconnection, and the third vertical interconnection are arranged at intervals in the row direction.

8. The display panel according to claim 3, wherein the plurality of stacked sub-pixels further comprise a functional layer, and the functional layer is provided between the anode and the light-emitting part, and between the light-emitting part and the cathode.

9. The display panel according to claim 1, further comprising non-stacked sub-pixels located on a side of the plurality of stacked sub-pixels; and
wherein the plurality of stacked sub-pixels form a pixel unit, or the plurality of stacked sub-pixels and the non-stacked sub-pixels together form the pixel unit.

10. The display panel according to claim 3, wherein a first step surface is provided between the first pixel opening and the second pixel opening, and a second step surface is provided between the second pixel opening and the third pixel opening.

11. The display panel according to claim 3, wherein sizes of the first pixel opening, the second pixel opening, and the third pixel opening gradually increase, and design spaces of the display panel occupied by the first light-emitting part, the second light-emitting part, and the third light-emitting part gradually increase.

12. The display panel according to claim 10, further comprising: a first insulating layer and a second insulating layer;
wherein the first insulating layer is provided at a bottom of the second pixel opening close to the substrate, and parts of two sides of the first insulating layer in the row direction are located on the first step surface; and
the second insulating layer is provided at a bottom of the third pixel opening of the third organic layer close to the substrate, and parts of two sides of the second insulating layer in the row direction are located on the second step surface.

13. The display panel according to claim 12, wherein the first insulating layer and the second insulating layer are light-transmitting film layers.

14. The display panel according to claim 7, wherein the first conductor layer further comprises a fourth vertical interconnection;
wherein the first cathode is connected to the driving circuit layer through the fourth vertical interconnection.

15. The display panel according to claim 7, wherein the first vertical interconnection is arranged below the second pixel opening, and the second vertical interconnection is arranged below the third pixel opening.

16. A method for manufacturing a display panel, applied to manufacture the display panel,
wherein the display panel comprises:
a substrate;
a driving circuit layer, provided on a side of the substrate;
a pixel definition layer, provided on a side of the driving circuit layer away from the substrate; and
a plurality of stacked sub-pixels, stacked on the side of the driving circuit layer away from the substrate in a vertical direction and located in the pixel definition layer;
wherein orthographic projections of at least some of the plurality of stacked sub-pixels on the driving circuit layer overlap; and
each stacked sub-pixel comprises an anode, a light-emitting part, and a cathode that are sequentially arranged and connected in a horizontal direction;
wherein the method comprises:
forming the driving circuit layer on the substrate;
forming the pixel definition layer on the side of the driving circuit layer away from the substrate; and
forming the plurality of stacked sub-pixels in pixel openings of the pixel definition layer, wherein the orthographic projections of at least some of the plurality of stacked sub-pixels on the driving circuit layer overlap.

17. A display device, comprising:
a display panel; and
a main board, connected to the display panel;
wherein the display panel comprises:
a substrate;
a driving circuit layer, provided on a side of the substrate;
a pixel definition layer, provided on a side of the driving circuit layer away from the substrate; and
a plurality of stacked sub-pixels, stacked on the side of the driving circuit layer away from the substrate in a vertical direction and located in the pixel definition layer;
wherein orthographic projections of at least some of the plurality of stacked sub-pixels on the driving circuit layer overlap; and
each stacked sub-pixel comprises an anode, a light-emitting part, and a cathode that are sequentially arranged and connected in a horizontal direction.

18. The display device according to claim 17, wherein the pixel definition layer comprises a first organic layer, a second organic layer, and a third organic layer;
wherein the second organic layer is located on a side of the first organic layer away from the substrate, and the third organic layer is located on a side of the second organic layer away from the substrate;
the first organic layer comprises a first pixel opening, the second organic layer comprises a second pixel opening, and the third organic layer comprises a third pixel opening;
the plurality of stacked sub-pixels comprise a first sub-pixel, a second sub-pixel, and a third sub-pixel; and
the first sub-pixel is located in the first pixel opening, the second sub-pixel is located in the second pixel opening, and the third sub-pixel is located in the third pixel opening.

19. The display device according to claim 18, wherein an orthographic projection of the first pixel opening on the second organic layer is located within the second pixel opening, and an orthographic projection of the second pixel opening on the third organic layer is located within the third pixel opening of the third organic layer;
wherein the horizontal direction comprises a row direction and a column direction that are perpendicular to each other;
the first sub-pixel comprises a first anode, a first light-emitting part, and a first cathode;
the first anode and the first cathode are respectively located on a first side wall and a second side edge of the first pixel opening in the row direction;
the second sub-pixel comprises a second anode, a second light-emitting part, and a second cathode;
the second anode and the second cathode are respectively located on a first side wall and a second side edge of the second pixel opening in the row direction;
the third sub-pixel comprises a third anode, a third light-emitting part, and a third cathode; and
the third anode, and the third cathode are respectively located on a first side wall and a second side edge of the third pixel opening in the row direction.

20. The display device according to claim 19, wherein a manufacturing material of the first light-emitting part comprises a green organic light-emitting material, a manufacturing material of the second light-emitting part comprises a red organic light-emitting material, and a manufacturing material of the third light-emitting part comprises a blue organic light-emitting material; and
the green organic light-emitting material, the red organic light-emitting material, and the blue organic light-emitting material are all light-transmitting materials.
